(19) United States
(12) Patent Application Publication
(10) Pub. No.: US 2022/0397824 A1
(43) Pub. Date: Dec. 15, 2022

(54) PHOTOSENSITIVE COMPOSITION, METHOD FOR FORMING PIXEL, METHOD FOR MANUFACTURING OPTICAL FILTER, METHOD FOR MANUFACTURING SOLID-STATE IMAGING ELEMENT, AND METHOD FOR MANUFACTURING IMAGE DISPLAY DEVICE

(71) Applicant: FUJIFILM Corporation, Tokyo (JP)

(72) Inventor: Shoichi NAKAMURA, Hailbara-gun (JP)

(73) Assignee: FUJIFILM Corporation, Tokyo (JP)

(21) Appl. No.: 17/880,235

(22) Filed: Aug. 3, 2022

Related U.S. Application Data
(63) Continuation of application No. PCT/JP2021/004476, filed on Feb. 8, 2021.

(30) Foreign Application Priority Data
Feb. 14, 2020 (JP) 2020-022930

(51) Int. Cl. G03F 7/004; G03F 7/028; G03F 7/00; G02B 5/22

(52) U.S. Cl. CPC G03F 7/0048; G03F 7/028; G03F 7/0007; G02B 5/223

(57) ABSTRACT

Provided are a photosensitive composition including a coloring material, a resin, a polymerizable compound, a photopolymerization initiator, and a solvent A, in which the solvent A includes a solvent A1 in which a surface tension at 25° C. is 28.0 mN/m or more, a viscosity at 25° C. is 5.0 mP·s or less, and a boiling point is 160° C. or higher, and a content of the solvent A1 in a total amount of the solvent A is 15% by mass or more; a method for forming a pixel formed of the photosensitive composition; a method for manufacturing an optical filter; a method for manufacturing a solid-state imaging element; and a method for manufacturing an image display device.

### CROSS-REFERENCE TO RELATED APPLICATIONS

This application is a Continuation of PCT International Application No. PCT/JP2021/004476 filed on Feb. 8, 2021, which claims priority under 35 U.S.C § 119(a) to Japanese Patent Application No. 2020-022930 filed on Feb. 14, 2020. Each of the above application(s) is hereby expressly incorporated by reference, in its entirety, into the present application.

### BACKGROUND OF THE INVENTION

### 1. Field of the Invention

The present invention relates to a photosensitive composition including a coloring material. The present invention further relates to a method for forming a pixel formed of the photosensitive composition, a method for manufacturing an optical filter, a method for manufacturing a solid-state imaging element, and a method for manufacturing an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element. The color filter normally includes pixels of three primary colors of red, green, and blue, and acts to separate transmitted light into the three primary colors.

Colored pixels of each color of the color filter are manufactured by forming a pattern by a photolithography method using a photosensitive composition including a coloring material.

JP2011-158687A discloses an invention relating to a coloring composition including the following components (A) to (F):
(A) a colorant;
(B) a copolymer which has at least one selected from the group consisting of a repeating unit (1) consisting of a monomer having an ammonium structure in a side chain and a repeating unit (2) consisting of a monomer having an amine structure in a side chain, a repeating unit (3) consisting of a (meth)acrylic acid ester monomer, and a repeating unit (4) consisting of a (meth)acrylic acid polyoxyalkylene monomer,
(C) a binder resin (excluding the component (B);
(D) a polyfunctional monomer;
(E) a photopolymerization initiator; and
(F) a solvent which contains a solvent (F1) having a boiling point of 180° C. or higher at 1 atm, in which a content proportion of the solvent (F1) is 1% to 40% by mass in a total solvent.

### SUMMARY OF THE INVENTION

In recent years, solid-state imaging elements equipped with an optical filter such as a color filter have been made smaller and have higher resolution. Therefore, a miniaturization of pixels has been studied for the optical filter such as a color filter.

However, in a case of forming a pixel on a support by a lithography method using a photosensitive composition, as the pixel to be formed is finer, there is a tendency for variations in a pattern size of the pixel formed on the support. In particular, the tendency is large as a thickness of the pixel is thinner.

Therefore, an object of the present invention is to provide a photosensitive composition that a pixel in which a variation in pattern size is suppressed can be formed by a photolithography method, a method for forming a pixel, a method for manufacturing an optical filter, a method for manufacturing a solid-state imaging element, and a method for manufacturing an image display device.

According to the studies conducted by the present inventor, it has been found that the above-described object can be achieved by adopting the following configuration, thereby leading to the completion of the present invention. Therefore, the present invention provides the following.

<1> A photosensitive composition comprising:

a coloring material;

a resin;

a polymerizable compound;

a photopolymerization initiator, and

a solvent A,

in which the solvent A includes a solvent A1 in which a surface tension at 25° C. is 28.0 mN/m or more, a viscosity at 25° C. is 5.0 mPa s or less, and a boiling point is 160° C. or higher, and

a content of the solvent A1 in a total amount of the solvent A is 15% by mass or more.

<2> The photosensitive composition according to <1>, further comprising:

a surfactant.

<3> The photosensitive composition according to <1> or <2>,

in which the boiling point of the solvent A1 is 160° C. to 280° C.

<4> The photosensitive composition according to any one of <1> to <3>,

in which a Hansen solubility parameter of the solvent A1 is 18.0 to 22.0 MPa^{0.5}.

<5> The photosensitive composition according to any one of <1> to <4>,

in which the solvent A1 is at least one selected from cyclohexyl acetate, 3-methoxy-1-butanol, or 1,2-diacetoxypropane.

<6> The photosensitive composition according to any one of <1> to <5>,

in which an absolute value of a difference between a Hansen solubility parameter of the photopolymerization initiator and a Hansen solubility parameter of the solvent A1 is 4.5 MPa^{0.5} or less.

<7> The photosensitive composition according to any one of <1> to <6>,

in which the coloring material includes a pigment.

<8> The photosensitive composition according to any one of <1> to <7>,

in which the photosensitive composition contains the coloring material in an amount of 38% by mass or more in a total solid content of the photosensitive composition.

<9> A method for forming a pixel, comprising:

a step of applying the photosensitive composition according to any one of <1> to <8> to a support to form a photosensitive composition layer;

a step of exposing the photosensitive composition layer in a patterned manner; and

a step of removing a non-exposed portion of the photosensitive composition layer after exposure by development.

<10> The method for forming a pixel according to <9>,

in which the photosensitive composition is applied to the support by a spin coating method to form the photosensitive composition layer.

<11> A method for manufacturing an optical filter, comprising:

the method for forming a pixel according to <9> or <10>.

<12> A method for manufacturing a solid-state imaging element, comprising:

the method for forming a pixel according to <9> or <10>.

<13> A method for manufacturing an image display device, comprising:

the method for forming a pixel according to <9> or <10>.

According to the present invention, it is possible to provide a photosensitive composition that a pixel in which a variation in pattern size is suppressed can be formed by a photolithography method, a method for forming a pixel, a method for manufacturing an optical filter, a method for manufacturing a solid-state imaging element, and a method for manufacturing an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in a structural formula, Me represents a methyl group, Et represents an ethyl group, Bu represents a butyl group, Pr represents a propyl group, and Ph represents a phenyl group.

In the present specification, a weight-average molecular weight and a number-average molecular weight are values in terms of polystyrene through measurement by a gel permeation chromatography (GPC) method.

In the present specification, near infrared rays denote light having a wavelength in a range of 700 to 2500 nm.

In the present specification, a total solid content denotes the total mass of all the components of the composition excluding a solvent.

In the present specification, a pigment means a compound which is hardly dissolved in a solvent. For example, as the pigment, both of the solubility in 100 g of water at 23° C. and 100 g of propylene glycol monomethyl ether acetate at 23° C. is preferably 0.1 g or less and more preferably 0.01 g or less.

In the present specification, the term “step” is not only an independent step, but also includes a step which is not clearly distinguished from other steps in a case where an intended action of the step is obtained.

<Photosensitive Composition>

A photosensitive composition according to an embodiment of the present invention includes a coloring material, a resin, a polymerizable compound, a photopolymerization initiator, and a solvent A, in which the solvent A includes a solvent A1 in which a surface tension at 25° C. is 28.0 mN/m or more, a viscosity at 25° C. is 5.0 mPa·s or less, and a boiling point is 160° C. or higher, and a content of the solvent A1 in a total amount of the solvent A is 15% by mass or more.

With the photosensitive composition according to the embodiment of the present invention, it is possible to form a pixel by a photolithography method, in which a variation in pattern size is suppressed. The reason why such an effect is obtained is presumed that, by including the above-described solvent A1, the photopolymerization initiator can be easily dispersed uniformly in a film after coating, and as a result, a polymerization reaction during exposure can be uniformly promoted. Therefore, with the photosensitive composition according to the embodiment of the present invention, it is presumed that it is possible to form a pixel in which a variation in pattern size is suppressed.

In particular, even in a case where the photosensitive composition according to the embodiment of the present invention is applied by a spin coating method used in a wafer process, it is presumed that the photopolymerization initiator can be more uniformly dispersed in the film after coating, and it is possible to form a pixel in which the variation in pattern size is further suppressed. For example, even in a case of forming a fine-sized pixel with a thin film (for example, a thickness of 0.5 μm or less) by applying the photosensitive composition according to the embodiment of the present invention to a support by a spin coating method and then forming the pixel by a lithography method, it is possible to suppress a variation in pattern size of the formed pixel. Therefore, the photosensitive composition according to the embodiment of the present invention exerts a particularly remarkable effect in a case of being used as a photosensitive composition for spin coating.

The photosensitive composition according to the embodiment of the present invention is preferably used as a photosensitive composition for an optical filter. Examples of the optical filter include a color filter, a near infrared transmitting filter, and a near infrared cut filter, and a color filter is preferable.

Examples of the color filter include a filter having a colored pixel which transmits light having a specific wavelength, and a filter having at least one colored pixel selected from a red pixel, a blue pixel, a green pixel, a yellow pixel, a cyan pixel, or a magenta pixel is preferable. The colored pixel of the color filter can be formed using a photosensitive composition containing a chromatic coloring material.

Examples of the near infrared cut filter include a filter having a maximal absorption wavelength in a wavelength range of 700 to 1800 nm. As the near infrared cut filter, a filter having a maximal absorption wavelength in a wavelength range of 700 to 1300 nm is preferable, and a filter having a maximal absorption wavelength in a wavelength range of 700 to 1000 nm is more preferable. In addition, in the near infrared cut filter, a transmittance of in the entire wavelength range of 400 to 650 nm is preferably 70% or more, more preferably 80% or more, and still more preferably 90% or more. In addition, the transmittance at at least one point in a wavelength range of 700 to 1800 nm is preferably 20% or less. In addition, in the near infrared cut filter, absorbance Aₘₐₓ/absorbance A₅₅₀, which is a ratio of an absorbance Aₘₐₓ at a maximal absorption wavelength to an absorbance A₅₅₀ at a wavelength of 550 nm, is preferably 20 to 500, more preferably 50 to 500, still more preferably 70 to 450, and particularly preferably 100 to 400. The near infrared cut filter can be formed using a photosensitive composition containing a near infrared absorbing coloring material.

The near infrared transmitting filter is a filter which transmits at least a part of near infrared rays. Examples of the near infrared transmitting filter include a filter which shields at least a part of visible light and transmits at least a part of near infrared rays. Preferred examples of the near infrared transmitting filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). The near infrared transmitting filter is preferably a filter which satisfies any one of the following spectral characteristics (1) to (4).

(1): filter in which the maximum value of a transmittance in a wavelength range of 400 to 640 nm is 20% or less (preferably 15% or less and more preferably 10% or less) and the minimum value of a transmittance in a wavelength range of 800 to 1300 nm is 70% or more (preferably 75% or more and more preferably 801% or more).

(2): filter in which the maximum value of a transmittance in a wavelength range of 400 to 750 nm is 20% or less (preferably 15% or less and more preferably 10% or less) and the minimum value of a transmittance in a wavelength range of 900 to 1300 nm is 70% or more (preferably 75% or more and more preferably 80% or more).

(3): filter in which the maximum value of a transmittance in a wavelength range of 400 to 830 nm is 20% or less (preferably 15% or less and more preferably 10% or less) and the minimum value of a transmittance in a wavelength range of 1000 to 1300 nm is 70% or more (preferably 75% or more and more preferably 80% or more).

(4): filter in which the maximum value of a transmittance in a wavelength range of 400 to 950 nm is 20% or less (preferably 15% or less and more preferably 10% or less) and the minimum value of a transmittance in a wavelength range of 1100 to 1300 nm is 70% or more (preferably 75% or more and more preferably 80% or more).

A concentration of solid contents of the photosensitive composition according to the embodiment of the present invention is preferably 5% to 40% by mass. The lower limit is preferably 8% by mass or more and more preferably 10% by mass or more. The upper limit is preferably 30% by mass or less, more preferably 25% by mass or less, and still more preferably 20% by mass or less.

Hereinafter, each of the components used in the photosensitive composition according to the embodiment of the present invention will be described.

<<Solvent A>>

The photosensitive composition according to the embodiment of the present invention contains a solvent A. The solvent A is preferably an organic solvent. Examples of the organic solvent include an aliphatic hydrocarbon-based solvent, a halogenated hydrocarbon-based solvent, an alcohol-based solvent, an ether-based solvent, an ester-based solvent, a ketone-based solvent, a nitrile-based solvent, an amide-based solvent, a sulfoxide-based solvent, and an aromatic solvent.

Examples of the aliphatic hydrocarbon-based solvent include hexane, cyclohexane, methylcyclohexane, pentane, cyclopentane, heptane, and octane.

Examples of the halogenated hydrocarbon-based solvent include methylene chloride, chloroform, dichloromethane, ethane dichloride, carbon tetrachloride, trichloroethylene, tetrachloroethylene, epichlorohydrin, monochlorobenzene, o-dichlorobenzene, allyl chloride, methyl monochloroacetate, ethyl monochloroacetate, monochloroacetic acid, trichloroacetic acid, methyl bromide, and tri(tetra)chloroethylene.

Examples of the alcohol-based solvent include methanol, ethanol, 1-propanol, 2-propanol, 2-butanol, ethylene glycol, propylene glycol, glycerin, 1,6-hexanediol, cyclohexanediol, sorbitol, xylitol, 2-methyl-2,4-pentanediol, 3-methoxy-1-butanol, 1,3-butanediol, and 1,4-butanediol.

Examples of the ether-based solvent include dimethyl ether, diethyl ether, diisopropyl ether, dibutyl ether, t-butyl methyl ether, cyclohexylmethyl ether, anisole, tetrahydrofuran, diethylene glycol, triethylene glycol, polyethylene glycol, dipropylene glycol, ethylene glycol monomethyl ether, ethylene glycol monobutyl ether, ethylene glycol monophenyl ether, propylene glycol monomethyl ether, propylene glycol monoethyl ether, propylene glycol monopropyl ether, propylene glycol monobutyl ether, diethylene glycol monomethyl ether, diethylene glycol monoethyl ether, diethylene glycol monopropyl ether, diethylene glycol monobutyl ether, diethylene glycol dimethyl ether, diethylene glycol diethyl ether, diethylene glycol dipropyl ether, diethylene glycol dibutyl ether, dipropylene glycol monomethyl ether, dipropylene glycol dimethyl ether, dipropylene glycol monoethyl ether, dipropylene glycol monopropyl ether, dipropylene glycol monobutyl ether, dipropylene glycol methyl-n-propyl ether, triethylene glycol monomethyl ether, triethylene glycol monobutyl ether, tripropylene glycol monomethyl ether, tripropylene glycol monobutyl ether, tetraethylene glycol dimethyl ether, polyethylene glycol monomethyl ether, and polyethylene glycol dimethyl ether.

Examples of the ester-based solvent include cyclohexyl acetate, 3-methoxy-1-butanol, 1,4-diacetoxybutane, 1,6-diacetoxyhexane, 1,2-diacetoxypropane, propylene carbonate, dipropylene, dipropylene glycol methyl ether acetate, methyl acetate, ethyl acetate, isopropyl acetate, n-propyl acetate, butyl acetate, ethylene glycol monomethyl ether acetate, propylene glycol monomethyl ether acetate, 3-methoxybutyl acetate, ethylene glycol monobutyl ether acetate, diethylene glycol monoethyl ether acetate, diethylene glycol monobutyl ether acetate, and triacetin.

Examples of the ketone-based solvent include acetone, methyl ethyl ketone, methyl isobutyl ketone, cyclopentanone, cyclohexanone, and 2-heptanone.

Examples of the nitrile-based solvent include acetonitrile.

Examples of the amide-based solvent include N,N-dimethylformamide, 1-methyl-2-pyrrolidone, 2-pyrrolidinone, 1,3-dimethyl-2-imidazolidinone, ε-caprolactam, formamide, N-methylformamide, acetamide, N-methylacetamide, N,N-dimethylacetamide, N-methylpropaneamide, hexamethylphosphoric triamide, 3-methoxy-N,N-dimethylpropaneamide, and 3-butoxy-N,N-dimethylpropaneamide.

Examples of the sulfoxide-based solvent include dimethyl sulfoxide.

Examples of the aromatic solvent include benzene and toluene.

In the present invention, as the solvent A, a solvent including a solvent A1 in which a surface tension at 25° C. is 28.0 mN/m or more, a viscosity at 25° C. is 5.0 mPa·s or less, and a boiling point is 160° C. or higher is used. In the present specification, the boiling point of a solvent is a value at 1 atm (0.1 MPa).

From the reason that the effects of the present invention can be easily obtained more significantly, the surface tension of the solvent A1 at 25° C. is preferably 28.0 to 35.0 mN/m, more preferably 28.5 to 34.5 mN/m, and still more preferably 29.0 to 34.0 mN/m. In the present specification, the surface tension of a solvent is a value measured by a plate method using a platinum plate. Hem, the measurement of the surface tension by the plate method is as follows. In a case where a probe (plate) touches the surface of the liquid, the liquid is wet with respect to the plate. In this case, a surface tension acts along a circumference of the plate and tries to draw the plate into the liquid. This pulling force is read and the surface tension of the liquid is measured. As a measuring device of the surface tension, a surface tension meter CBVP-Z manufactured by Kyowa Interface Science Co., Ltd. can be used.

The boiling point of the solvent A1 is preferably 160° C. to 280° C., more preferably 160° C. to 250° C., and more preferably 165° C. to 230° C. In a case where the boiling point of the solvent A1 is within the above-described range, it is possible to form a pixel in which the variation in pattern size is further suppressed. Further, coating properties of the photosensitive composition are good, and it is possible to suppress a variation in thickness of the formed pixel. This is particularly effective in a case of forming a thin pixel.

From the reason that the effects of the present invention can be easily obtained more significantly, the viscosity of the solvent A1 at 25° C. is preferably 1.0 to 5.0 mPa's, more preferably 1.5 to 4.0 mPa·s, and still more preferably 2.0 to 3.5 mPa·s.

A Hansen solubility parameter of the solvent A1 is preferably 18.0 to 22.0 MPa^{0.5}, more preferably 18.5 to 21.0 MPa^{0.5}, and still more preferably 19.0 to 20.0 MPa^{0.5}.

In the present specification, the Hansen solubility parameter of the solvent and a photopolymerization initiator described later is a value calculated using a Hansen solubility parameter software “HSPiP 5.0.09”.

Specific examples of the solvent A1 include cyclohexyl acetate (surface tension at 25° C.=30.5 mN/m, viscosity at 25° C.=2.0 mPa·s, boiling point: 173° C., Hansen solubility parameter: 18.2 MPa^{0.5}), 3-methoxy-1-butanol (surface tension at 25° C.=28.9 mN/m, viscosity at 25° C.=2.9 mPa·s, boiling point: 161° C., Hansen solubility parameter: 21.2 MPa^{0.5}), 1,2-diacetoxypropane (surface tension at 25° C.=31.2 mN/m, viscosity at 25° C.=2.7 mPa·s, boiling point: 190° C., Hansen solubility parameter: 19.1 MPa^{0.5}), 1,4-diacetoxybutane (surface tension at 25° C.=34.2 mN/m, viscosity at 25° C.=3.1 mPa·s, boiling point: 232° C., Hansen solubility parameter: 18.8 MPa^{0.5}), and 1,6-diacetoxyhexane (surface tension at 25° C.=34.1 mN/m, viscosity at 25° C.=3.9 mPa·s, boiling point: 260° C., Hansen solubility parameter: 18.3 MPa^{0.5}). Among these, from the reason that the effects of the present invention can be obtained more remarkably, the solvent A1 is at least one from cyclohexyl acetate, 3-methoxy-1-butanol, or 1,2-diacetoxypropane, and more preferably 1,2-diacetoxypropane.

The solvent A used in the photosensitive composition according to the embodiment of the present invention contains 15% by mass or more of the above-described solvent A1, preferably contains 25% by mass or more thereof and more preferably contains 30% by mass or more thereof. According to this aspect, the above-described effects of the present invention are easily obtained remarkably. From the viewpoint of dispersion stability of the coloring material in the composition, the upper limit thereof is preferably 80% by mass or less, more preferably 60% by mass or less, and still more preferably 40% by mass or less. The solvent A1 may be used singly or in a combination of two or more kinds thereof. In a case where two or more kinds thereof are included, the total amount thereof is preferably within the above-described range.

The solvent used in the photosensitive composition according to the embodiment of the present invention can further include a solvent (hereinafter, also referred to as a solvent A2) having a boiling point of lower than 160° C. By using the solvent A1 and the solvent A2 in combination, the above-described effects of the present invention can be obtained more remarkably.

The boiling point of the solvent A2 is preferably 115° C. or higher, more preferably 120° C. or higher, and still more preferably 130° C. or higher. In addition, the boiling point of the solvent A2 is preferably 155° C. or lower and more preferably 150° C. or lower. In a case where the boiling point of the solvent A2 is within the above-described range, the above-described effects of the present invention are easily obtained more remarkably.

A viscosity of the solvent A2 at 25° C. is preferably 0.5 to 5.0 mPa·s, more preferably 0.5 to 3.0 mPa·s, and still more preferably 0.5 to 1.5 mPa·s.

A surface tension of the solvent A2 at 25° C. is preferably less than 28.0 mN/m, more preferably 21.0 to 27.5 mN/m, and still more preferably 21.0 to 27.0 mN/m.

A Hansen solubility parameter of the solvent A2 is preferably 10.0 to 30.0 MPa^{0.5} and more preferably 15.0 to 25.0 MPa^{0.5}. In addition, an absolute value of the Hansen solubility parameter of the solvent A2 and the Hansen solubility parameter of the solvent A1 is preferably 5.0 MPa^{0.5} or less, more preferably 3.0 MPa^{0.5} or less, and still more preferably 2.0 MPa^{0.5} or less.

The solvent A2 is preferably at least one selected from an ether-based solvent or an ester-based solvent, more preferably includes at least an ester-based solvent, and still more preferably includes an ether-based solvent and an ester-based solvent. Specific examples of the solvent A2 include propylene glycol monomethyl ether acetate, propylene glycol monomethyl ether, cyclohexanone, cyclopentanone, ethyl lactate, butyl acetate, and propyl acetate, and propylene glycol monomethyl ether acetate is preferable.

In a case where the solvent A used in the photosensitive composition according to the embodiment of the present invention contains the solvent A2, a content of the solvent A2 is preferably 500 to 5000 parts by mass with respect to 100 parts by mass of the solvent A1. The upper limit is preferably 4000 parts by mass or less, more preferably 3000 parts by mass or less, and still more preferably 1500 parts by mass or less. The lower limit is preferably 600 parts by mass or more, more preferably 700 parts by mass or more, and still more preferably 750 parts by mass or more. In addition, the content of the solvent A2 in the total amount of the solvent is preferably 15% by mass or more, more preferably 30% by mass or more, and still more preferably 40% by mass or more. The upper limit is preferably 85% by mass or less, more preferably 80% by mass or less, still more preferably 70% by mass or less, and even more preferably 60% by mass or less. In a case where the content of the solvent A2 is within the above-described range, the effects of the present invention are easily obtained more remarkably. The solvent A2 may be used singly or in a combination of two or more kinds thereof. In a case where two or more kinds thereof are included, the total amount thereof is preferably within the above-described range.

In addition, the solvent A used in the photosensitive composition according to the embodiment of the present invention preferably contains 50% to 100% by mass of the total of the solvent A1 and the solvent A2, more preferably contains 60% to 100% by mass thereof, and still more preferably contains 70% to 100% by mass thereof.

The solvent A used in the photosensitive composition according to the embodiment of the present invention can further contain a solvent (hereinafter, also referred to as a solvent A3) other than the solvent A1 and the solvent A2. Examples of the solvent A3 include a solvent in which a boiling point is 160° C. or higher and a surface tension at 25° C. is less than 28.0 mN/m, and a solvent in which a boiling point is 160° C. or higher and a viscosity at 25° C. is more than 5.0 mPa·s.

In a case where the solvent A used in the photosensitive composition according to the embodiment of the present invention contains the solvent A3, a content of the solvent A3 is preferably 500 to 5000 parts by mass with respect to 100 parts by mass of the solvent A1. The upper limit is preferably 4000 parts by mass or less, more preferably 3000 parts by mass or less, and still more preferably 1500 parts by mass or less. The lower limit is preferably 600 parts by mass or more, more preferably 700 parts by mass or more, and still more preferably 750 parts by mass or more. In addition, it is also preferable that the solvent used in the photosensitive composition according to the embodiment of the present invention does not substantially contain the solvent A3. The case where the solvent does not substantially contain the solvent A3 means that the content of the solvent A3 in the total amount of the solvent is 0.1% by mass or less, preferably 0.05% by mass or less and more preferably 0% by mass.

A content of the solvent A in the photosensitive composition according to the embodiment of the present invention is preferably 60% to 95% by mass. The upper limit is preferably 92% by mass or less and more preferably 90% by mass or less. The lower limit is preferably 70% by mass or more, more preferably 75% by mass or more, and still more preferably 80% by mass or more.

The content of the solvent A1 in the photosensitive composition according to the embodiment of the present invention is preferably 20% to 80% by mass. The upper limit is preferably 70% by mass or less and more preferably 60% by mass or less. The lower limit is preferably 25% by mass or more and more preferably 30% by mass or more.

<<Coloring Material>>

The photosensitive composition according to the embodiment of the present invention contains a coloring material. Examples of the coloring material include a chromatic coloring material, a white coloring material, a black coloring material, and a near infrared absorbing coloring material. In a case of using a chromatic coloring material as the coloring material, the photosensitive composition according to the embodiment of the present invention can be preferably used as a photosensitive composition for forming a colored pixel in a color filter.

The coloring material may be a pigment or a dye. The pigment and the dye may be used in combination. In addition, the pigment may be either an inorganic pigment or an organic pigment. In addition, as the pigment, a material in which a part of an inorganic pigment or an organic-inorganic pigment is substituted with an organic chromophore can also be used. By substituting an inorganic pigment or an organic-inorganic pigment with an organic chromophore, hue design can be easily performed.

An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the photosensitive composition is good. In the present invention, the primary particle diameter of the pigment can be determined from a captured image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is an arithmetic average of the primary particle diameters with respect to 400 primary particles of the pigment. In addition, the primary particle of the pigment refers to a particle which is independent without aggregation.

The coloring material used in the present invention preferably includes the pigment. A content of the pigment in the coloring material is preferably 50% by mass or more, more preferably 70% by mass or more, still more preferably 80% by mass or more, and particularly preferably 90% by mass or more.

(Chromatic Coloring Material)

Examples of the chromatic coloring material include a coloring material having a maximal absorption wavelength in a wavelength range of 400 to 700 nm. Examples thereof include a yellow coloring material, an orange coloring material, a red coloring material, a green coloring material, a violet coloring material, and a blue coloring material. Specific examples of the chromatic coloring material include the following.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green coloring material. Specific examples thereof include the compounds described in WO2015/118720A. In addition, as the green coloring material, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, as the blue coloring material, an aluminum phthalocyanine compound having a phosphorus atom can also be used. Specific examples thereof include the compounds described in paragraphs 0022 to 0030 of JP2012-247591A and paragraph 0047 of JP2011-157478A.

In addition, as the yellow coloring material, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432077B, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-054339A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, a compound represented by Formula (QP1), a compound represented by Formula (QP2), compounds described in KR10-2014-0034963A, compounds described in JP2017-095706A, compounds described in TW2019-20495A, and compounds described in JP6607427B can also be used. In addition, from the viewpoint of improving a color value, a multimerized compound of these compounds is also preferably used. In addition, as the yellow coloring material, from the viewpoint of improving resistance, it is also preferable to use C. I. Pigment Yellow 129 or C. I. Pigment Yellow 215.

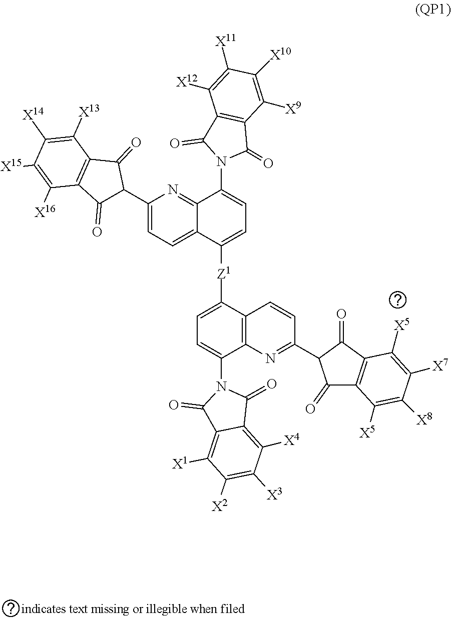

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

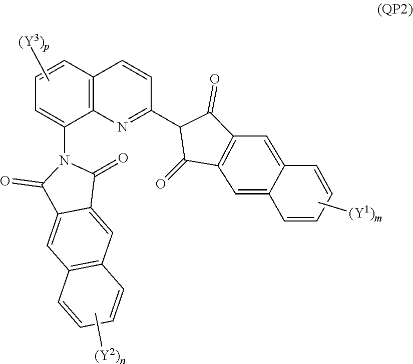

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

A diketopyrrolopyrrole pigment described in JP2017-201384A, in which the structure has at least one substituted bromine atom, a diketopyrrolopyrrole pigment described in paragraph Nos. 0016 to 0022 of JP6248838B, a red coloring material described in JP6516119B, a red coloring material described in JP6525101B, and the like can also be used as the red coloring material. In addition, as the red coloring material, a compound having a structure that an aromatic ring group in which a group bonded with an oxygen atom, a sulfur atom, or a nitrogen atom is introduced to an aromatic ring is bonded to a diketopyrrolopyrrole skeleton can also be used.

Regarding diffraction angles preferably possessed by various pigments, descriptions of JP6561862B, JP6413872B, and JP6281345B can be referred to, the contents of which are incorporated herein by reference.

In addition, a dye can also be used as the chromatic coloring material. The dye is not particularly limited and a known dye can be used. Examples thereof include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound. In addition, the thiazole compound described in JP2012-158649A, the azo compound described in JP2011-184493A, or the azo compound described in JP2011-145540A can also be used. In addition, as the dye, a coloring agent multimer can also be used. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structure or different coloring agent structures. A weight-average molecular weight (Mw) of the coloring agent multimer is preferably 2000 to 50000. The lower limit is more preferably 3000 or more and still more preferably 6000 or more. The upper limit is more preferably 30000 or less and still more preferably 20000 or less. As the coloring agent multimer, the compounds described in JP2011-213925A, JP2013-041097A, JP2015-028144A, JP2015-030742A, JP2016-102191A, WO2016/031442A, or the like can also be used.

The chromatic coloring material may be used in a combination of two or more kinds thereof. For example, C. I. Pigment Green 7, C. I. Pigment Green 36, C. I. Pigment Yellow 139, and C. I. Pigment Yellow 185 may be combined to form green, or C. I. Pigment Green 58, C. I. Pigment Yellow 150, and C. I. Pigment Yellow 185 may be combined to form green.

In addition, in a case where the chromatic coloring material is used in a combination of two or more kinds thereof, the combination of two or more kinds of chromatic coloring materials may form black. Examples of such a combination include the following aspects (1) to (7). In a case where two or more chromatic coloring materials are included in the photosensitive composition and the combination of two or more chromatic coloring materials forms black, the photosensitive composition according to the embodiment of the present invention can be preferably used as a photosensitive composition for forming the near infrared transmitting filter.

(1) aspect in which a red coloring material and a blue coloring material are contained.

(2) aspect in which a red coloring material, a blue coloring material, and a yellow coloring material are contained.

(3) aspect in which a red coloring material, a blue coloring material, a yellow coloring material, and a violet coloring material are contained.

(4) aspect in which a red coloring material, a blue coloring material, a yellow coloring material, a violet coloring material, and a green coloring material are contained.

(5) aspect in which a red coloring material, a blue coloring material, a yellow coloring material, and a green coloring material are contained.

(6) aspect in which a red coloring material, a blue coloring material, and a green coloring material are contained.

(7) aspect in which a yellow coloring material and a violet coloring material are contained.

(White Coloring Material)

Examples of the white coloring material include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white coloring material is preferably particles having a titanium atom, more preferably titanium oxide. In addition, the white coloring material is preferably a particle having a refractive index of 2.10 or more with respect to light having a wavelength of 589 nm. The above-mentioned refractive index is preferably 2.10 to 3.00 and more preferably 2.50 to 2.75.

In addition, as the white coloring material, the titanium oxide described in “Titanium Oxide-Physical Properties and Applied Technology, written by Manabu Kiyono, pages 13 to 45, published in Jun. 25, 1991, published by Gihodo Shuppan Co., Ltd.” can also be used.

The white coloring material is not limited to a compound formed of a single inorganic substance, and may be particles combined with other materials. For example, it is preferable to use a particle having a pore or other materials therein, a particle having a number of inorganic particles attached to a core particle, or a core-shell composite particle composed of a core particle formed of polymer particles and a shell layer formed of inorganic fine nanoparticles. With regard to the core-shell composite particle, reference can be made to the description in paragraph Nos. 0012 to 0042 of JP2015-047520A, the content of which is incorporated herein by reference.

As the white coloring material, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

(Black Coloring Material)

The black coloring material is not particularly limited, and a known black coloring material can be used. Examples of an inorganic black coloring material include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black coloring material include Color Index (C. I.) Pigment Black 1 and 7. It is preferable that the titanium black has a small primary particle diameter of the individual particles and has a small average primary particle diameter. Specifically, an average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.). Examples of an organic black coloring material include a bisbenzofuranone compound, an azomethine compound, a perylene compound, and an azo compound. Among these, a bisbenzofuranone compound or a perylene compound is preferable. Examples of the bisbenzofuranone compound include compounds described in JP2010-534726A, JP2012-515233A, JP2012-515234A, WO2014/208348A, JP2015-525260A, and the like, and the bisbenzofuranone compound is available, for example, as “Irgaphor Black” manufactured by BASF SE. Examples of the perylene compound include C. I. Pigment Black 31 and 32. Examples of the azomethine compound include the compounds described in JP1989-170601A (JP-H01-170601A) and JP1990-034664A (JP-H02-034664A), and the azomethine compound is available, for example, “CHROMOFINE BLACK A1103” manufactured by Dainichiseika Color & Chemicals Mfg. Co., Ltd. In addition, as the organic black coloring material, perylene black (Lumogen Black FK4280 and the like) described in paragraphs 0016 to 0020 of JP2017-226821A may be used.

(Near Infrared Absorbing Coloring Material)

The near infrared absorbing coloring material is preferably a pigment, and more preferably an organic pigment. In addition, the near infrared absorbing coloring material is preferably a compound having a maximal absorption wavelength in a wavelength range of more than 700 nm and 1400 nm or less. In addition, the maximal absorption wavelength of the near infrared absorbing coloring material is preferably 1200 nm or less, more preferably 1000 nm or less, and still more preferably 950 nm or less. In addition, in the near infrared absorbing coloring material, A₅₅₀/Aₘₐₓ, which is a ratio of an absorbance A₅₅₀ at a wavelength of 550 nm to an absorbance Aₘₐₓ at the maximal absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near infrared absorbing coloring material excellent in visible transparency and near infrared shielding properties can be obtained. In the present invention, the maximal absorption wavelength of the near infrared absorbing coloring material and values of absorbance at each wavelength are values obtained from an absorption spectrum of a film formed by using a photosensitive composition including the near infrared absorbing coloring material.

The near infrared absorbing coloring material is not particularly limited, and examples thereof include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, and a dithiolene metal complex. Examples of the pyrrolopyrrole compound include compounds described in paragraph Nos. 0016 to 0058 of JP2009-263614A, compounds described in paragraph Nos. 0037 to 0052 of JP2011-068731A, and compounds described in paragraph Nos. 0010 to 0033 of WO2015/166873A. Examples of the squarylium compound include compounds described in paragraph Nos. 0044 to 0049 of JP2011-208101A, compounds described in paragraph Nos. 0060 and 0061 of JP6065169B, compounds described in paragraph No. 0040 of WO2016/181987A, compounds described in JP2015-176046A, compounds described in paragraph No. 0072 of WO2016/190162A, compounds described in paragraph Nos. 0196 to 0228 of JP2016-074649A, compounds described in paragraph No. 0124 of JP2017-067963A, compounds described in WO2017/135359A, compounds described in JP2017-114956A, compounds described in JP6197940B, and compounds described in WO2016/120166A. Examples of the cyanine compound include compounds described in paragraph Nos. 0044 and 0045 of JP2009-108267A, compounds described in paragraph Nos. 0026 to 0030 of JP2002-194040A, compounds described in JP2015-172004A, compounds described in JP2015-172102A, compounds described in JP2008-088426A, compounds described in paragraph No. 0090 of WO2016/190162A, and compounds described in JP2017-031394A. Examples of the croconium compound include compounds described in JP2017-082029A. Examples of the iminium compound include compounds described in JP2008-528706A, compounds described in JP2012-012399A, compounds described in JP2007-092060A, and compounds described in paragraph Nos. 0048 to 0063 of WO2018/043564A. Examples of the phthalocyanine compound include compounds described in paragraph No. 0093 of JP2012-077153A, oxytitanium phthalocyanine described in JP2006-343631A, compounds described in paragraph Nos. 0013 to 0029 of JP2013-195480A, and vanadium phthalocyanine compounds described in JP6081771B. Examples of the naphthalocyanine compound include compounds described in paragraph No. 0093 of JP2012-077153A. Examples of the dithiolene metal complex include compounds described in JP5733804B.

As the near infrared absorbing coloring material, squarylium compounds described in JP2017-197437A, squarylium compounds described in JP2017-025311A, squarylium compounds described in WO2016/154782A, squarylium compounds described in JP5884953B, squarylium compounds described in JP6036689B, squarylium compounds described in JP5810604B, squarylium compounds described in paragraph Nos. 0090 to 0107 of WO2017/213047A, pyrrole ring-containing compounds described in paragraph Nos. 0019 to 0075 of JP2018-054760A, pyrrole ring-containing compounds described in paragraph Nos. 0078 to 0082 of JP2018-040955A, pyrrole ring-containing compounds described in paragraph Nos. 0043 to 0069 of JP2018-002773A, squarylium compounds having an aromatic ring at the α-amide position described in paragraph Nos. 0024 to 0086 of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029, asymmetric compounds described in paragraph Nos. 0027 to 0114 of JP2017-068120A, pyrrole ring-containing compounds (carbazole type) described in JP2017-067963A, phthalocyanine compounds described in JP6251530B, and the like can also be used.

A content of the coloring material in the total solid content of the photosensitive composition is preferably 30% to 80% by mass. The lower limit is preferably 38% by mass or more and more preferably 42% by mass or more. The upper limit is preferably 75% by mass or less and more preferably 70% by mass or less.

In addition, a content of the pigment in the total solid content of the photosensitive composition is preferably 30% to 80% by mass. The lower limit is preferably 38% by mass or more and more preferably 42% by mass or more. The upper limit is preferably 75% by mass or less and more preferably 70% by mass or less.

<<Resin>>

The coloring composition according to the embodiment of the present invention contains a resin. The resin is blended in, for example, an application for dispersing a pigment or the like in the coloring composition or an application as a binder. Mainly, a resin which is used for dispersing a pigment or the like in the coloring composition is also referred to as a dispersant. However, such applications of the resin are merely exemplary, and the resin can also be used for other purposes in addition to such applications.

A weight-average molecular weight (Mw) of the resin is preferably 3000 to 2000000. The upper limit is preferably 1000000 or less, more preferably 500000 or less, still more preferably 100000 or less, even more preferably 70000 or less, and particularly preferably 50000 or less. The lower limit is preferably 5000 or more, more preferably 7000 or more, and still more preferably 10000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof.

The coloring composition according to the embodiment of the present invention preferably contains a resin having an acid group. Examples of the acid group include a carboxyl group, a phosphoric acid group, a sulfo group, and a phenolic hydroxy group. Among these acid groups, one kind may be used singly, or two or more kinds may be used in combination. The resin having an acid group can also be used as a dispersant. In a case where the coloring composition according to the embodiment of the present invention contains a resin having an acid group, a desired pattern can be formed by an alkali development. An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 200 mgKOH/g or less, still more preferably 150 mgKOH/g or less, and most preferably 120 mgKOH/g or less.

The resin also preferably includes a resin including a repeating unit derived from a compound represented by Formula (ED1) and/or a compound represented by Formula (ED2) (hereinafter, these compounds will also be referred to as an “ether dimer”).

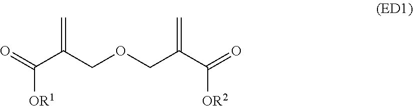

In Formula (ED1), R¹ and R² each independently represent a hydrogen atom or a hydrocarbon group having 1 to 25 carbon atoms, which may have a substituent.

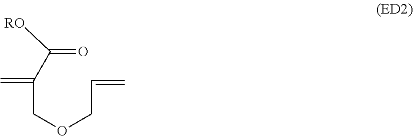

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph No. 0317 of JP2013-029760A, the contents of which are incorporated herein by reference.

The resin also preferably includes a resin including a repeating unit having a polymerizable group.

The resin also preferably includes a resin including a repeating unit derived from a compound represented by Formula (X).

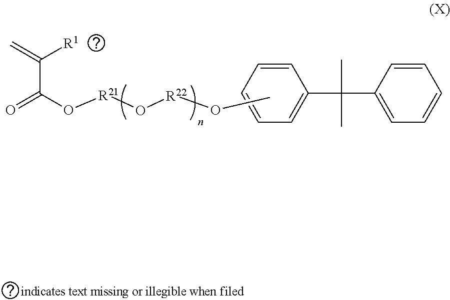

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

As the resin, it is also preferable to include a resin (hereinafter, also referred to as a resin Ac) having an aromatic carboxyl group. The resin Ac may include the aromatic carboxyl group in the main chain of the repeating unit, or in the side chain of the repeating unit. It is preferable that the aromatic carboxyl group is included in the main chain of the repeating unit. In the present specification, the aromatic carboxyl group is a group having a structure in which one or more carboxyl groups are bonded to an aromatic ring. In the aromatic carboxyl group, the number of carboxyl groups bonded to an aromatic ring is preferably 1 to 4 and more preferably 1 or 2.

The resin preferably includes a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group is 70 mol % or more in a case where the total amount of the acid group and the basic group is 100 mol %. The acid group included in the acidic dispersant (acidic resin) is preferably a carboxyl group. An acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a resin (resin Ac) having an aromatic carboxyl group. Examples of the resin having an aromatic carboxyl group include those described above.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

It is also preferable that the resin used as a dispersant are a resin including a repeating unit having an ethylenically unsaturated bond-containing group in the side chain. A content of the repeating unit having an ethylenically unsaturated bond-containing group in the side chain is preferably 10 mol % or more, more preferably 10 to 80 mol %, and still more preferably 20 to 70 mol % with respect to the total repeating units of the resin. In addition, as the dispersant, a resin described in JP2018-087939A can also be used.

A commercially available product is also available as the dispersant, and specific examples thereof include DISPERBYK series manufactured by BYK Chemie Japan, Solsperse series manufactured by Lubrizol Japan Ltd., Efka series manufactured by BASF SE, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

In addition, as the resin used as a dispersant, block copolymers (EB-1) to (EB-9) described in paragraph Nos. 0219 to 0221 of JP6432077B can also be used.

A content of the resin in the total solid content of the photosensitive composition is preferably 1% to 70% by mass. The lower limit is preferably 5% by mass or more, more preferably 10% by mass or more, still more preferably 15% by mass or more, and particularly preferably 20% by mass or more. The upper limit is preferably 60% by mass or less, more preferably 50% by mass or less, and still more preferably 45% by mass or less. The resin may be used alone or in a combination of two or more kinds thereof. In a case where two or more kinds of resins are used, the total amount thereof is preferably within the above-described range.

<<Polymerizable Compound>>

The photosensitive composition according to the embodiment of the present invention contains a polymerizable compound. Examples of the polymerizable compound include a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer Company Inc.) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), DPHA-40H (manufactured by Nippon Kayaku Co., Ltd.), UA-306H, UA-306T, UA-3061, AH-600, T-600, AI-600, and LINC-202UA (manufactured by KYOEISHA CHEMICAL Co., LTD.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

In addition, as the polymerizable compound, a compound having an acid group can also be used. By using a polymerizable compound having an acid group, the polymerizable compound in a non-exposed portion is easily removed during development and the generation of a development residue can be suppressed. Examples of the acid group include a carboxyl group, a sulfo group, and a phosphoric acid group, and a carboxyl group is preferable. Examples of a commercially available product of the polymerizable compound having an acid group include ARONIX M-510, M-520, and ARONIX TO-2349 (manufactured by TOAGOSEI CO., LTD). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

In addition, as the polymerizable compound, a compound having a caprolactone structure can also be used. Examples of a commercially available product of the polymerizable compound having a caprolactone structure include KAYARAD DPCA-20, DPCA-30, DPCA-60, and DPCA-120 (all manufactured by Nippon Kayaku Co., Ltd.).

In addition, as the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer Company Inc., which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

In addition, as the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

A content of the polymerizable compound in the total solid content of the photosensitive composition is preferably 0.1% to 50% by mass. The lower limit is more preferably 0.5% by mass or more and still more preferably 1% by mass or more. The upper limit is more preferably 45% by mass or less, still more preferably 40% by mass or less, even more preferably 30% by mass or less, and even still more preferably 20% by mass or less. The polymerizable compound may be used singly or in a combination of two or more kinds thereof. In a case where two or more kinds of polymerizable compounds are used, the total amount thereof is preferably within the above-described range.

<<Photopolymerization Initiator>>

The photosensitive composition according to the embodiment of the present invention contains a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of a commercially available product of the α-hydroxyketone compound include Omnirad 184, Omnirad 1173, Omnirad 2959, and Omnirad 127 (all of which are manufactured by 1GM Resins B.V.), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Onmirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by 1GM Resins B.V.), Irgacure 819 and Irgacure TPO (both of which are manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF SE), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound which are preferably used in the present invention are shown below, but the present invention is not limited thereto.

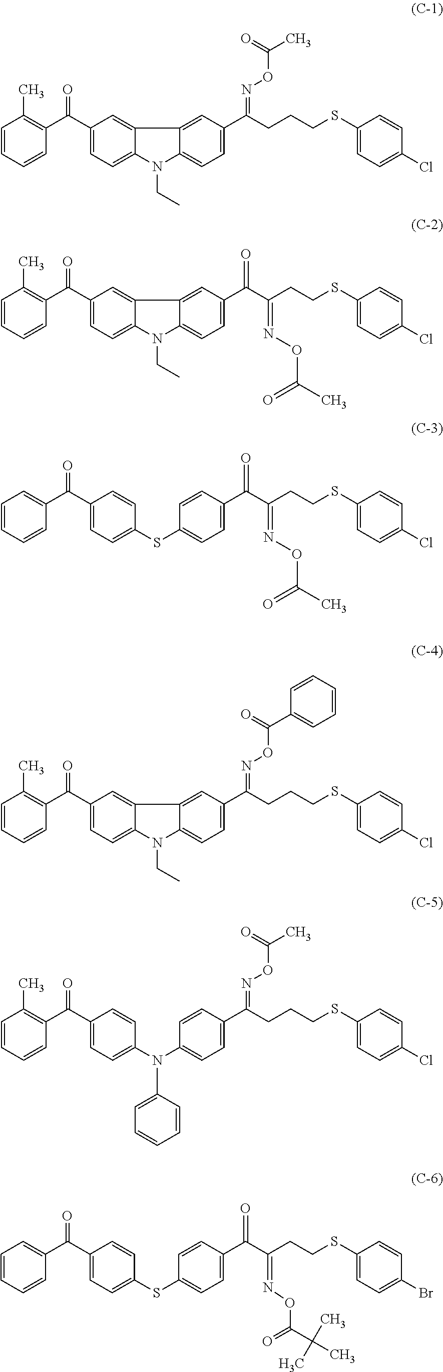 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

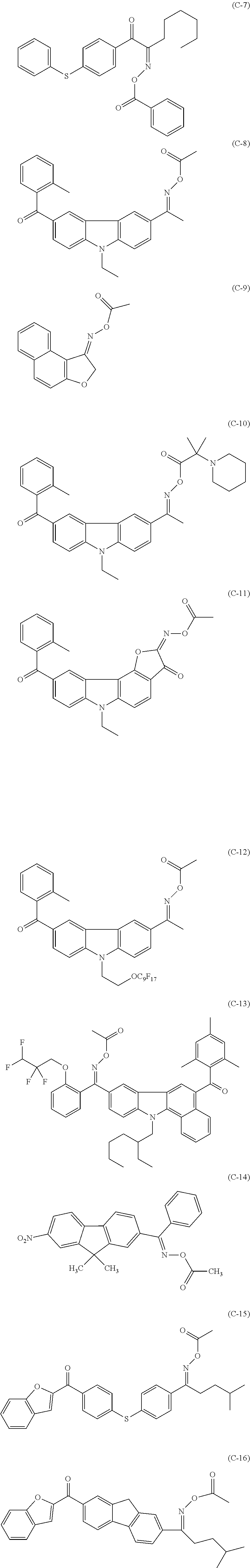

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian Medical Systems, Inc.) using an ethyl acetate solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the photosensitive composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

A Hansen solubility parameter of the photopolymerization initiator is preferably 19.0 to 23.0 MPa^{0.5}, more preferably 20.0 to 22.5 MPa^{0.5}, and still more preferably 20.5 to 22.0 MPa^{0.5}.

In addition, an absolute value of the Hansen solubility parameter of the photopolymerization initiator and the Hansen solubility parameter of the solvent A1 is preferably 4.5 MPa^{0.5} or less, more preferably 4.0 MPa^{0.5} or less, and still more preferably 3.5 MPa^{0.5} or less. According to this aspect, the photopolymerization initiator can be more uniformly dispersed in the photosensitive composition, and it is possible to form a pixel in which the variation in pattern size is remarkably suppressed.

A content of the photopolymerization initiator in the total solid content of the photosensitive composition is preferably 0.1% to 20% by mass. The lower limit is preferably 0.5% by mass or more and more preferably 1% by mass or more. The upper limit is preferably 15% by mass or less, more preferably 10% by mass or less, and still more preferably 5% by mass or less. The photopolymerization initiator may be used singly or in a combination of two or more kinds thereof. In a case where two or more kinds of photopolymerization initiators are used, the total amount thereof is preferably within the above-described range.

<<Pigment Derivative>>

The photosensitive composition according to the embodiment of the present invention can contain a pigment derivative. In a particular, in a case of including the pigment as the coloring material, the photosensitive composition according to the embodiment of the present invention preferably contains a pigment derivative. Examples of the pigment derivative include a compound having a structure in which an acid group or a basic group is bonded to a coloring agent skeleton. Examples of the coloring agent skeleton constituting the pigment derivative include a quinoline coloring agent skeleton, a benzoimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a quinacridone coloring agent skeleton, a dioxazine coloring agent skeleton, a perinone coloring agent skeleton, a perylene coloring agent skeleton, a thioindigo coloring agent skeleton, an isoindrin coloring agent skeleton, a isoindolinone coloring agent skeleton, a quinophthalone coloring agent skeleton, a dithiol coloring agent skeleton, a triarylmethane coloring agent skeleton, and a pyrromethene coloring agent skeleton. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be contained. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in Example described later and compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A.

In a case where the photosensitive composition contains a pigment derivative, a content of the pigment derivative is preferably 1 to 30 parts by mass, more preferably 3 to 25 parts by mass, and still more preferably 5 to 20 parts by mass with respect to 100 parts by mass of the pigment. The pigment derivative may be used singly or in a combination of two or more kinds thereof. In a case where two or more kinds thereof are used in combination, the total amount thereof is preferably within the above-described range.

<<Surfactant>>

The photosensitive composition according to the embodiment of the present invention preferably contains a surfactant. According to this aspect, it is possible to form a pixel in which the variation in pattern size is further suppressed. As the surfactant, various surfactants such as a fluorine-based surfactant, a nonionic surfactant, a cationic surfactant, an anionic surfactant, and a silicone-based surfactant can be used. Examples of the surfactant include surfactants described in paragraph Nos. 0238 to 0245 of WO2015/166779A, the contents of which are incorporated herein by reference.

The surfactant is preferably a fluorine-based surfactant or a silicone-based surfactant. In the present specification, the silicone-based surfactant is a compound having a repeating unit including a siloxane bond in the main chain, and is a compound including a hydrophobic part and a hydrophilic part in one molecule.

A fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the photosensitive composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

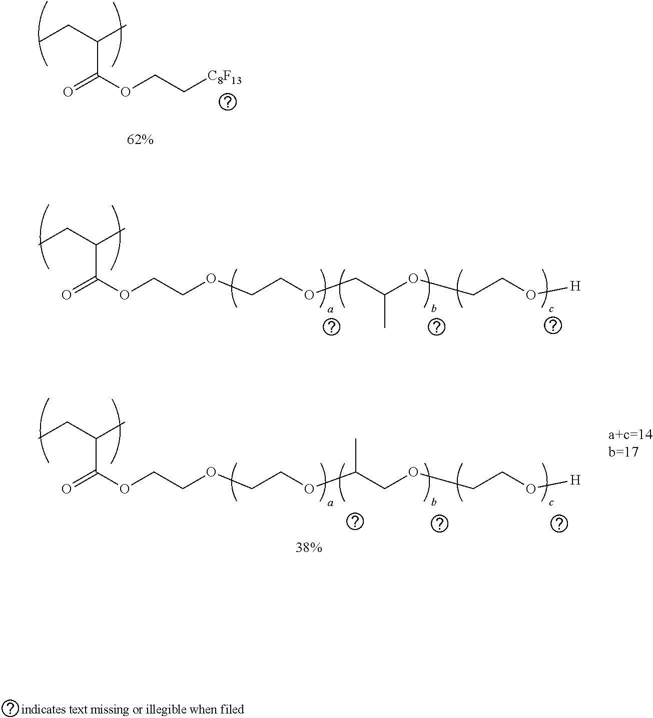

A weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

The silicone-based surfactant is preferably a modified silicone compound. Examples of the modified silicone compound include compounds having a structure in which an organic group is introduced into a side chain and/or a terminal of polysiloxane. Examples of the organic group include a group having a functional group selected from an amino group, an epoxy group, an alicyclic epoxy group, a carbinol group, a mercapto group, a carboxyl group, a fatty acid ester group, and a fatty acid amide group, and a group having a polyether chain. From the reason that the effects of the present invention can be easily obtained more significantly, the organic group is preferably a group having a carbinol group or a group having a polyether chain.

Examples of the group including a carbinol group include a group represented by Formula (G-1).

-L^{G1}-CH₂OH (G-1)

In Formula (G-1), L^{G1} represents a single bond or a linking group. Examples of the linking group represented by L^{G1} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

The group including a carbinol group is preferably a group represented by Formula (G-2).

-L^{G2}-O-L^{G3}-CH₂OH (G-2)

In Formula (G-2), L^{G2} and L^{G3} each independently represent a single bond or an alkylene group (preferably an alkylene group having 1 to 12 carbon atoms and more preferably an alkylene group having 1 to 6 carbon atoms), and preferably represent an alkylene group.

Examples of the group including a polyether chain include a group represented by Formula (G-11) and a group represented by Formula (G-12).

-L^{G11}-(R^{G1}O)ₙ₁R^{G2} (G-11)

-L^{G11}-(OR^{G1})ₙ₁OR^{G2} (G-12)

In Formula (G-11) and Formula (G-12), L^{G11} represents a single bond or a linking group. Examples of the linking group represented by L^{G11} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

In Formula (G-11) and Formula (G-12), n1 represents a number of 2 or more, and is preferably 2 to 200.

In Formula (G-11) and Formula (G-12), R^{G1} represents an alkylene group. The alkylene group preferably has 1 to 10 carbon atoms, more preferably has 1 to 5 carbon atoms, still more preferably has 1 to 3 carbon atoms, and particularly preferably has 2 or 3 carbon atoms. The alkylene group represented by R^{G1} may be linear or branched. The alkylene groups represented by n1 pieces of R^{G1}'s may be the same or different from each other.

In Formula (G-11) and Formula (G-12), R^{G2} represents a hydrogen atom, an alkyl group, or an aryl group. The alkyl group represented by R^{G2} preferably has 1 to 10 carbon atoms, more preferably has 1 to 5 carbon atoms, and still more preferably has 1 to 3 carbon atoms. The alkyl group may be linear or branched. The aryl group represented by R^{G2} preferably has 6 to 20 carbon atoms and more preferably has 6 to 10 carbon atoms.

The group including a polyether chain is preferably a group represented by Formula (G-13) or a group represented by (G-14).

-L^{G12}(C₂H₄O)ₙ₂(C₃H₆O)ₙ₃R^{G3} (G-13)

-L^{G12}-(OC₂H₄)ₙ₂(OC₃H₆)ₙ₃OR^{G3} (G-14)

In Formula (G-13) and Formula (G-14), L_{G12} represents a single bond or a linking group. Examples of the linking group represented by L^{G12} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

In Formula (G-13) and Formula (G-14), n2 and n3 each independently represent a number of 1 or more, and are preferably 1 to 100.

In Formula (G-13) and Formula (G-14), R^{G3} represents a hydrogen atom, an alkyl group, or an aryl group. The alkyl group represented by R^{G3} preferably has 1 to 10 carbon atoms, more preferably has 1 to 5 carbon atoms, and still more preferably has 1 to 3 carbon atoms. The alkyl group may be linear or branched. The aryl group represented by R^{G3} preferably has 6 to 20 carbon atoms and more preferably has 6 to 10 carbon atoms.

The modified silicone compound is preferably a compound represented by Formulae (Si-1) to (Si-5).

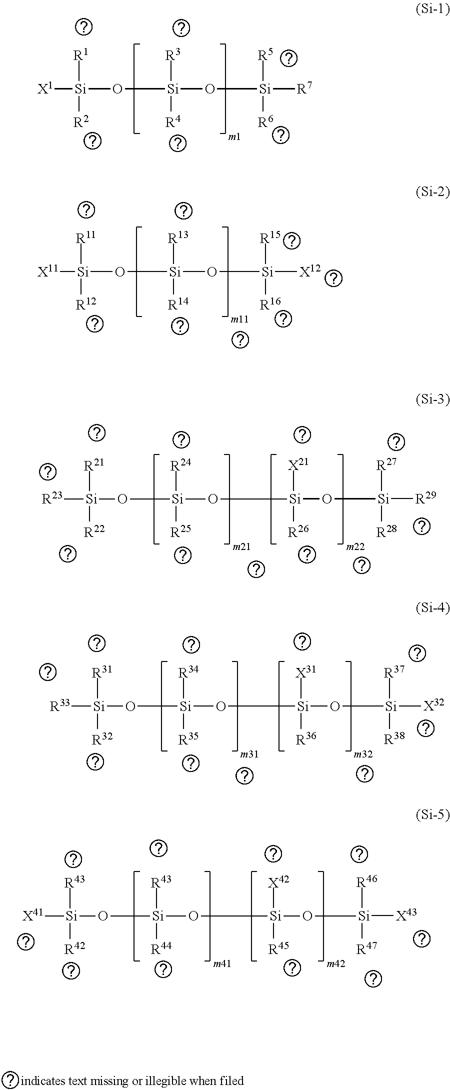

In Formula (Si-1), R¹ to R⁷ each independently represent an alkyl group or an aryl group.

X¹ represents a group having a functional group selected from an amino group, an epoxy group, an alicyclic epoxy group, a carbinol group, a mercapto group, a carboxyl group, a fatty acid ester group, and a fatty acid amide group, or a group having a polyether chain.

m1 represents a number of 2 to 200.

The alkyl group represented by R¹ to R⁷ preferably has 1 to 10 carbon atoms, more preferably has 1 to 5 carbon atoms, still more preferably has 1 to 3 carbon atoms, and particularly preferably has 1 carbon atom. The alkyl group represented by R¹ to R⁷ may be linear or branched, but is preferably linear. The aryl group represented by R¹ to R⁷ preferably has 6 to 20 carbon atoms, more preferably has 6 to 12 carbon atoms, and particularly preferably has 6 carbon atoms. R¹ to R⁷ are each preferably a methyl group or a phenyl group, and more preferably a methyl group.

X¹ is preferably a group including a carbinol group or a group including a polyether chain, and more preferably a group including a carbinol group. The preferred range of the group including a carbinol group and the group including a polyether chain is the same as the above-described range.

In Formula (Si-2), R¹¹ to R¹⁶ each independently represent an alkyl group or an aryl group.

X¹¹ and X¹² each independently represent a group having a functional group selected from an amino group, an epoxy group, an alicyclic epoxy group, a carbinol group, a mercapto group, a carboxyl group, a fatty acid ester group, and a fatty acid amide group, or a group having a polyether chain.

m11 represents a number of 2 to 200.

R¹¹ to R¹⁶ in Formula (Si-2) have the same meanings as R¹ to R⁷ in Formula (Si-1), and preferred ranges thereof are also the same. X¹¹ and X¹² in Formula (Si-2) have the same meanings as X¹ in Formula (Si-1), and preferred ranges thereof are also the same.

In Formula (Si-3), R²¹ to R²⁹ each independently represent an alkyl group or an aryl group.

X²¹ represents a group having a functional group selected from an amino group, an epoxy group, an alicyclic epoxy group, a carbinol group, a mercapto group, a carboxyl group, a fatty acid ester group, and a fatty acid amide group, or a group having a polyether chain.

m21 and m22 each independently represent an integer of 1 to 199, and in a case where m22 represents 2 or more, m22 x²¹'s may be the same as or different from each other.

R²¹ to R²⁹ in Formula (Si-3) have the same meanings as R¹ to R⁷ in Formula (Si-1), and preferred ranges thereof are also the same. X²¹ in Formula (Si-3) have the same meanings as X¹ in Formula (Si-1), and preferred ranges thereof are also the same.

In Formula (Si-4), R³¹ to R³⁸ each independently represent an alkyl group or an aryl group.

X³¹ and X³² each independently represent a group having a functional group selected from an amino group, an epoxy group, an alicyclic epoxy group, a carbinol group, a mercapto group, a carboxyl group, a fatty acid ester group, and a fatty acid amide group, or a group having a polyether chain.

m31 and m32 each independently represent an integer of 1 to 199, and in a case where m32 represents 2 or more, m32 x³¹'s may be the same as or different from each other.

R³¹ to R³⁸ in Formula (Si-4) have the same meanings as R¹ to R⁷ in Formula (Si-1), and preferred ranges thereof are also the same. X³¹ and X³² in Formula (Si-4) have the same meanings as X¹ in Formula (Si-1), and preferred ranges thereof are also the same.

In Formula (Si-5), R⁴¹ to R⁴⁷ each independently represent an alkyl group or an aryl group.

X⁴¹ and X⁴³ each independently represent a group having a functional group selected from an amino group, an epoxy group, an alicyclic epoxy group, a carbinol group, a mercapto group, a carboxyl group, a fatty acid ester group, and a fatty acid amide group, or a group having a polyether chain.

m41 and m42 each independently represent an integer of 1 to 199, and in a case where m42 represents 2 or more, m42 x⁴²'s may be the same as or different from each other.

R⁴¹ to R⁴⁷ in Formula (Si-5) have the same meanings as R¹ to R⁷ in Formula (Si-1), and preferred ranges thereof are also the same. X⁴¹ to X⁴³ in Formula (Si-4) have the same meanings as X¹ in Formula (Si-1), and preferred ranges thereof are also the same.

Specific examples of the silicone-based surfactant include compounds described below in Examples. In addition, Examples of a commercially available product of the silicone-based surfactant include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Corporation); Silwet L-77, L-7280, L-7001, L-7002, L-7200, L-7210, L-7220, L-7230, L7500, L-7600, L-7602, L-7604, L-7605, L-7622, L-7657, L-8500, and L-8610 (all of which are manufactured by Momentive Performance Materials Inc.): KP-341, KF-6001, and KF-6002 (all of which are manufactured by Shin-Etsu Chemical Co., Ltd.); and BYK307, BYK323, and BYK330 (all of which are manufactured by BYK-Chemie Japan K.K.).

A content of the surfactant in the total solid content of the photosensitive composition is preferably 0.001% by mass to 5.0% by mass. The lower limit is preferably 0.005% by mass or more and more preferably 0.01% by mass or more. The upper limit is preferably 3.0% by mass or less, more preferably 1.0% by mass or less, still more preferably 0.3% by mass or less, even more preferably 0.2% by mass or less, and particularly preferably 0.1% by mass or less. The surfactant may be used singly or in a combination of two or more kinds thereof. In a case where two or more kinds thereof are used, the total amount thereof is preferably within the above-described range.

<<Compound Having Cyclic Ether Group>>

The photosensitive composition can contain a compound having a cyclic ether group. Examples of the cyclic ether group include an epoxy group and an oxetanyl group. It is preferable that the compound having a cyclic ether group is a compound having an epoxy group (hereinafter, also referred to as an “epoxy compound”). Examples of the epoxy compound include a compound having one or more epoxy groups in one molecule, and a compound having two or more epoxy groups in one molecule is preferable. The epoxy compound is preferably a compound having 1 to 100 epoxy groups in one molecule. The upper limit of the number of epoxy groups included in the epoxy compound may be, for example, 10 or less or 5 or less. The lower limit of the epoxy group included in the epoxy compound is preferably 2 or more. As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the compound having an epoxy group is preferably 200 to 100000 and more preferably 500 to 50000. The upper limit of the weight-average molecular weight is still more preferably 10000 or less, particularly preferably 5000 or less, and even more preferably 3000 or less.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

In a case where the photosensitive composition according to the embodiment of the present invention contains a compound having a cyclic ether group, a content of the compound having a cyclic ether group in the total solid content of the photosensitive composition is preferably 0.1% to 20% by mass. The lower limit is, for example, more preferably 0.5% by mass or more and still more preferably 1% by mass or more. The upper limit is, for example, more preferably 15% by mass or less and still more preferably 10% by mass or less. The compound having a cyclic ether group may be used singly or in a combination of two or more kinds thereof. In a case where two or more kinds thereof are used, the total amount thereof is preferably within the above-described range.

<<Silane Coupling Agent>>

The photosensitive composition according to the embodiment of the present invention can contain a silane coupling agent. According to this aspect, adhesiveness of a film to be obtained with a support can be further improved. In the present specification, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

A content of the silane coupling agent in the total solid content of the photosensitive composition is preferably 0.1% to 5% by mass. The upper limit is more preferably 3% by mass or less and still more preferably 2% by mass or less. The lower limit is more preferably 0.5% by mass or more and still more preferably 1% by mass or more. The silane coupling agent may be used singly or in a combination of two or more kinds thereof. In a case where two or more kinds thereof are used, the total amount thereof is preferably within the above-described range.

<<Ultraviolet Absorber>>

The photosensitive composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. A content of the ultraviolet absorber in the total solid content of the photosensitive composition is preferably 0.01% to 10% by mass and more preferably 0.01% to 5% by mass. The ultraviolet absorber may be used singly or in a combination of two or more kinds thereof. In a case where two or more kinds thereof are used, the total amount thereof is preferably within the above-described range.

<<Polymerization Inhibitor>>

The photosensitive composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. A content of the polymerization inhibitor in the total solid content of the photosensitive composition is preferably 0.0001% to 5% by mass. The polymerization inhibitor may be used singly or in a combination of two or more kinds thereof. In a case of two or more kinds thereof, the total amount thereof is preferably within the above-described range.

<<Other Components>>

Optionally, the photosensitive composition according to the embodiment of the present invention can contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, as desired, the photosensitive composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

In order to adjust the refractive index of a film to be obtained, the photosensitive composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The photosensitive composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

In the photosensitive composition according to the embodiment of the present invention, the content of liberated metals which are not bonded to or coordinated with a pigment or the like is preferably 100 ppm or less, more preferably 50 ppm or less, and still more preferably 10 ppm or less, it is particularly preferable to not contain the liberated metals substantially. According to this aspect, effects such as stabilization of pigment dispersibility (restraint of aggregation), improvement of spectral characteristics due to improved dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described liberated metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the photosensitive composition according to the embodiment of the present invention, the content of liberated halogen which is not bonded to or coordinated with a pigment or the like is preferably 100 ppm or less, more preferably 50 ppm or less, and still more preferably 10 ppm or less, it is particularly preferable to not contain the liberated halogen substantially. Examples of halogen include F, Cl, Br, I, and anions thereof. Examples of a method for reducing liberated metals and halogens in the photosensitive composition include washing with ion exchange water, filtration, ultrafiltration, and purification with an ion exchange resin.

It is also preferable that the photosensitive composition according to the embodiment of the present invention does not substantially include terephthalic acid ester. Here, the “does not substantially include” means that the content of terephthalic acid ester is 1000 mass ppb or less in the total amount of the photosensitive composition, and it is more preferable to be 100 mass ppb or less and particularly preferable to be 0.

<<Storage Container>>

A storage container for the photosensitive composition is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or photosensitive compositions. Examples of such a container include the containers described in JP2015-123351A. In addition, for the purpose of preventing metal elution from the container interior wall, improving storage stability of the photosensitive composition, and suppressing the alteration of components, it is also preferable that the container interior wall is formed of glass, stainless steel, or the like.

<Method for Preparing Photosensitive Composition>

The photosensitive composition according to the embodiment of the present invention can be prepared by mixing the above-described components with each other. In the preparation of the photosensitive composition, all the components may be dissolved and/or dispersed at the same time in a solvent to prepare the photosensitive composition, or the respective components may be appropriately left in two or more solutions or dispersion liquids and mixed to prepare the photosensitive composition upon use (during coating), as desired.

In addition, in the preparation of the photosensitive composition, a process for dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

It is preferable that, in the preparation of the photosensitive composition, the photosensitive composition is filtered through a filter for the purpose of removing foreign matters, reducing defects, or the like. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha, Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Method for Forming Pixel>

A method for forming a pixel according to an embodiment of the present invention includes a step of applying the above-described photosensitive composition according to the embodiment of the present invention to a support to form a photosensitive composition layer, a step of exposing the photosensitive composition layer in a patterned manner, and a step of removing a non-exposed portion of the photosensitive composition layer after exposure by development. Hereinafter, the respective steps will be described.

In the step of forming a photosensitive composition layer, the photosensitive composition is applied to a support to form the photosensitive composition layer. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. A surface contact angle of the base layer is preferably 20° to 70° in a case of being measured with diiodomethane. In addition, the surface contact angle of the base layer is preferably 30° to 800 in a case of being measured with water. In a case where the surface contact angle of the base layer is within the above-described range, coating property of the photosensitive composition is good. The surface contact angle of the base layer can be adjusted by, for example, adding a surfactant.

As a method of applying the photosensitive composition, a known method can be used. Examples thereof include a dropping method (drop casting); a slit coating method; a spray method; a roll coating method; a spin coating method; a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet—Infinite Possibilities in Patent—” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the photosensitive composition, reference can be made to the description in WO2017/030174A and WO2017/018419A, the contents of which are incorporated herein by reference.

Among these, from the reason that the effects of the present invention can be easily obtained more significantly, a spin coating method is preferable as the method for applying the photosensitive composition. That is, in the present invention, it is preferable that the photosensitive composition is applied to the support by a spin coating method to form a photosensitive composition layer.

The photosensitive composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the photosensitive composition layer is exposed in a patterned manner (exposing step). For example, the photosensitive composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, a non-exposed portion of the photosensitive composition layer after exposure is removed by development (developing step). The removal of the non-exposed portion of the photosensitive composition layer by development can be carried out using a developer. Thus, the photosensitive composition layer of the non-exposed portion is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkali agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the photosensitive composition layer after development while rotating the support on which the photosensitive composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film (pixel) after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

In this way, the pixel can be formed.

A film thickness of the formed pixel can be adjusted according to the purpose. For example, the film thickness is preferably 10 μm or less, more preferably 5 μm or less, still more preferably 1 μm or less, and even more preferably 0.5 μm or less. The lower limit of the film thickness is preferably 0.1 μm or more, more preferably 0.2 μm or more, and still more preferably 0.3 μm or more.

A line width (size) of the formed pixel can be adjusted according to the purpose. For example, the line width is preferably 2.0 μm or less, more preferably 1.2 μm or less, and still more preferably 1.0 μm or less. The lower limit of the line width is preferably 0.4 μm or more, more preferably 0.5 μm or more, and still more preferably 0.6 μm or more.

<Method for Manufacturing Optical Filter>

A method for manufacturing an optical filter according to an embodiment of the present invention includes the above-described method for forming a pixel according to the embodiment of the present invention. Examples of the type of the optical filter include a color filter, a near infrared cut filter, and a near infrared transmitting filter, and a color filter is preferable. The color filter preferably has the pixel formed of the photosensitive composition according to the embodiment of the present invention as a colored pixel thereof. In addition, in a case where the color filter has pixels of a plurality of colors, by performing the above-described method for forming a pixel according to the embodiment of the present invention for each color pixel, a color filter having a plurality of color pixels can be formed. The color filter may be, for example, a filter having one or more colors of colored pixels such as a red pixel, a blue pixel, a green pixel, a cyan pixel, a magenta pixel, and a yellow pixel. Specific examples of the color filter include a filter having at least a red pixel, a blue pixel and a green pixel, and a filter having at least a cyan pixel, a magenta pixel and a yellow pixel. The color filter may have a structure in which each colored pixel is embedded in a space partitioned in, for example, a lattice shape by a partition wall. The partition wall in this case preferably has a low refractive index for each colored pixel.

<Method for Manufacturing Solid-State Imaging Element>

A method for manufacturing a solid-state imaging element according to an embodiment of the present invention includes the above-described method for forming a pixel according to the embodiment of the present invention. A configuration of the solid-state imaging element of the present invention is not particularly limited, and examples thereof include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice shape by a partition wall. The partition wall in this case preferably has a low refractive index for each colored pixel. Examples of an imaging device having such a structure include the devices described in JP2012-227478A, JP2014-179577A, and WO2018/043654A. In addition, as in JP2019-211559A, an ultraviolet absorbing layer may be provided in the structure of the solid-state imaging element to improve light resistance. An imaging device including the solid-state imaging element can also be used as a vehicle camera or a surveillance camera, in addition to a digital camera or electronic apparatus (mobile phones or the like) having an imaging function.

<Method for Manufacturing Image Display Device>

A method for manufacturing an image display device according to an embodiment of the present invention includes the above-described method for forming a pixel according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### Examples

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Measuring Method of Weight-Average Molecular Weight>

A weight-average molecular weight (Mw) of a resin was calculated by Gel permeation chromatography (GPC) measurement under the following measurement conditions.

Types of columns: columns formed by connection of TOSOH TSKgel Super HZM-H, TOSOH TSKgel Super HZ4000, and TOSOH TSKgel Super HZ2000

Developing solvent: tetrahydrofuran

Column temperature: 40° C.

Flow rate (amount of a sample to be injected): 1.0 μL (sample concentration: 0.1% by mass)

Device name: HLC-8220GPC manufactured by Tosoh Corporation

Detector: differential refractometer (RI detector)

Calibration curve base resin: polystyrene resin

<Measurement of Viscosity>

A viscosity of a measurement sample was measured with a viscometer (product name “RE-85 type viscometer, manufactured by Toki Sangyo Co., Ltd.). Measurement conditions of the viscosity were set to a rotation speed of 20 rpm and a temperature of the measurement sample of 25° C.

<Measurement of Surface Tension of Solvent>

After adjusting a temperature of a solvent to 25° C., a surface tension of the solvent was measured with a plate method using a platinum plate and a surface tensiometer CBVP-Z (manufactured by Kyowa Interface Science Co., Ltd.) as a measuring device.

<Production of Photosensitive Composition>

Materials described in the following table were mixed to prepare a photosensitive composition. As a dispersion liquid, a dispersion liquid prepared as follows was used.

After mixing the coloring material 1, the coloring material 2, the pigment derivative, the dispersant, and the solvent 1 of types described in the column of the dispersion liquid of the following table to each other in an amount of parts by mass shown in the following table, the mixture was mixed and dispersed for 3 hours by a beads mill (zirconia beads: 0.3 mm diameter), and then subjected to a dispersion treatment under a pressure of 2,000 kg/cm² at a flow rate of 500 g/min using a high-pressure disperser equipped with a pressure-reducing system NANO-3000-10 (manufactured by Nippon BEE Chemical Co., Ltd.). After repeating this dispersion treatment 10 times, the beads were separated by filtration to produce a dispersion liquid.

TABLE 1

| | | Dispersion liquid | | | | | | Poly- | Photopoly- | | | |
|---|---|---|---|---|---|---|---|---|---|---|---|---|
| | | Coloring | Coloring | Pigment | Dis- | Solvent | | merizable | merization | | Solvent | Solvent |
| | | material 1 | material 2 | derivative | persant | 1 | Binder | compound | initiator | Surfactant | 2 | 3 |
| Example 1 | Material | PR254 | PY139 | P-1 | D-1 | A2-1 | B-1 | M-1 | 1-1 | F-1 | A2-1 | Al-1 |
| | Content | 4.2 | 1.8 | 0.6 | 2.3 | 35.6 | 4.0 | 1.5 | 0.6 | 0.02 | 28.1 | 21.2 |
| Example 2 | Material | PR254 | PY139 | P-1 | D-1 | A2-1 | B-1 | M-1 | 1-1 | F-1 | A2-3 | Al-1 |
| | Content | 4.2 | 1.8 | 0.6 | 2 3 | 35.6 | 4.0 | 1.5 | 0.6 | 0.02 | 19.6 | 29.7 |
| Example 3 | Material | PR254 | PY139 | P-1 | D-1 | A2-1 | B-I | M-1 | 1-1 | F-1 | A2-1 | Al-1 |
| | Content | 4.2 | 1.8 | 0.6 | 2.3 | 35.6 | 4.0 | 1.5 | 0.6 | 0 02 | 11.1 | 38.2 |
| Example 4 | Material | PR254 | PY139 | P-1 | D-1 | A2-1 | B-1 | M-1 | 1-1 | F-1 | A2-1 | Al-1 |
| | Content | 4.2 | 1.8 | 0.6 | 2.3 | 35.6 | 4.0 | 1.5 | 0.6 | 0.02 | 2.6 | 46.7 |
| | Material | PR254 | PY139 | P-1 | D-1 | A 2-1 | B-1 | M-1 | 3-1 | F-1 | A2-1 | A1-2 |
| Laatupte | Content | 4.2 | 1.8 | 0.6 | 2.3 | 35.6 | 4.0 | 15 | 0 6 | 0.02 | 19 6 | 29.7 |
| Example 6 | Material | PR254 | PY139 | P-1 | D-1 | A 7.1 | B-1 | M-1 | 1-1 | F-1 | A2-1 | A1.2 |
| | Content | 4.2 | 1.8 | 0.6 | 2.3 | 35.6 | 4.0 | 1.5 | 0.6 | 0.02 | 11 | 38.2 |
| Example 7 | Material | PR254 | PY139 | P-1 | D-1 | A2-1 | B-1 | M-1 | 1-1 | F-1 | A2-1 | A1-3 |
| | Content | 4.2 | 1.8 | 0.6 | 2.3 | 35.6 | 4.0 | 1.5 | 0.6 | 0.02 | 19.6 | 29.7 |
| Example 8 | Material | PR254 | PY139 | P-1 | D-1 | A2-1 | B-1 | M-1 | 3-1 | F-1 | A2-1 | A1-3 |
| | Content | 4.2 | 1.8 | 0.6 | 2.3 | 35.6 | 4.0 | 1.5 | 0.6 | 0.02 | 11.1 | 38.2 |
| Example 9 | Material | PG58 | PY185 | P-1 | D-1 | A2-1 | B-1 | M-1 | 1-1 | F-1 | A2-1 | Al-3 |
| | Content | 4.2 | 1.8 | 0.6 | 2 3 | 35.6 | 4.0 | 1.5 | 0.6 | 0.02 | 11.1 | 38.2 |
| Example 10 | Material | PG36 | PY185 | P-1 | D-1 | A23 | B-1 | M-1 | 1-3 | F-1 | A2-1 | A1-3 |
| | Content | 4.2 | 1.8 | 0.6 | 2.3 | 35.6 | 4.0 | 1.5 | 0.6 | 0 02 | 11.1 | 38.2 |
| Example 11 | Material | PB15:6 | PV23 | P-1 | D-1 | A2-1 | B-1 | M-1 | 1-1 | F-1 | A2-1 | A1-3 |
| | Content | 4.2 | 1.8 | 0.6 | 2.3 | 35.6 | 4.0 | 1.5 | 0.6 | 0.02 | 11.1 | 38.2 |
| Example 12 | Material | PR254 | PY139 | P-1 | D-1 | A 2-1 | B-1 | M-1 | 3-1 | F-1 | A2-1 | A1-3 |
| | Content | 4.2 | 1.8 | 0.6 | 2.3 | 35.6 | 3.9 | 15 | 0 6 | 0.08 | 11.2 | 38.3 |
| Example 13 | Material | PR254 | PY139 | P-1 | D-1 | A 7.1 | B-1 | M-1 | 1-2 | F-1 | A2-1 | A1-3 |
| | Content | 4.2 | 1.8 | 0.6 | 2.3 | 35.6 | A £ | 1.5 | 0.6 | 0.02 | 11 | 38.2 |
| Example 14 | Material | PR254 | PY139 | P-1 | D-1 | A2-1 | B-1 | M-1 | 1-3 | F-1 | A2-1 | A1-3 |
| | Content | 4.2 | 1.8 | 0.6 | 2.3 | 35.6 | 4.0 | 1.5 | 0.6 | 0.02 | 11.1 | 38.2 |
| Example 15 | Material | PR254 | PY139 | P-1 | D-1 | A2-1 | B-1 | M-1 | 3-4 | F-1 | A2-1 | A1-3 |
| | Content | 4.2 | 1.8 | 0.6 | 2.3 | 35.6 | 4.0 | 1.5 | 0.6 | 0.02 | 11.1 | 38.2 |
| Example 16 | Material | PR254 | PY139 | P-1 | D-1 | AZ..] | B-1 | M-1 | 1-5 | F-1 | A2-1 | Al-3 |
| | Content | 4.2 | 1.8 | 0.6 | 2.3 | 35.6 | 4.0 | 1.5 | 0.6 | 0.02 | 11.1 | 38.2 |
| Example 1 7 | Material | PR254 | PY139 | P-1 | D-1 | A23 | B-1 | M-1 | 1-1 | F-2 | A2-1 | A1-3 |
| | Content | 4.2 | 1.8 | 0.6 | 2.3 | 35.6 | 4.0 | 1.5 | 0.6 | 0 02 | 11.1 | 38.2 |
| Example 18 | Material | PR254 | PY139 | P-1 | D-1 | A2-1 | B-1 | M-1 | 1-5 | | A2-1 | A1-3 |
| | Content | 4.2 | 1.8 | 0.6 | 2.3 | 35.6 | 4.0 | 1.5 | 0.6 | | 11.2 | 38.3 |
| Comparative | Material | PR254 | PY139 | P-1 | D-1 | A 2-1 | B-1 | M-1 | 1-1 | F-1 | A2-3 | A2-2 |
| Example 1 | Content | 4.2 | 1.8 | 0.6 | 2 3 | 35.6 | 4.0 | 1.5 | 0.6 | 0.02 | 11.1 | 38.2 |
| Comparati ve | Material | PR254 | PY139 | P-1 | D-1 | A 7.1 | B-1 | M-1 | 1-5 | F-1 | A2-1 | A2-3 |
| Example 2 | Content | 4.2 | 1.8 | 0.6 | 2.3 | 35.6 | 4.0 | 1.5 | 0.6 | 0.02 | 11.1 | 38.2 |

The materials described in the materials of the above table are as follows.

(Coloring Material)

PR254: C. I. Pigment Red 254 (red pigment)

PY 139: C. I. Pigment Yellow 139 (yellow pigment)

PY 185: C. I. Pigment Yellow 185 (yellow pigment)

PG58: C. I. Pigment Green 58 (green pigment)

PG36: C. I. Pigment Green 36 (green pigment)

PB15:6: C. I. Pigment Blue 15:6 (blue pigment)

PV23: C. I. Pigment Violet 23 (violet pigment)

(Pigment Derivative)

P-1: compound having the following structure

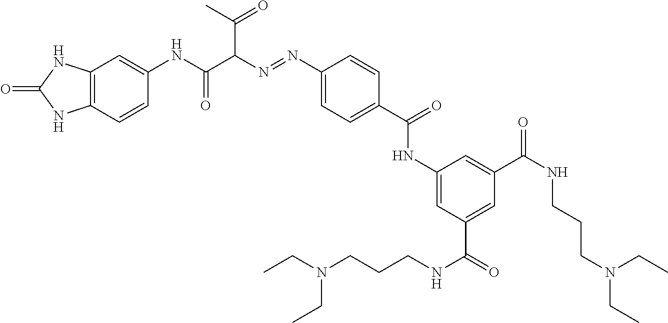 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

(Dispersant)

D-1: resin having the following structure (a numerical value added to a main chain represents a molar ratio of a repeating unit, and a numerical value added to a side chain represents the number of repeating units; Mw: 20000, acid value: 75 mgKOH/g)

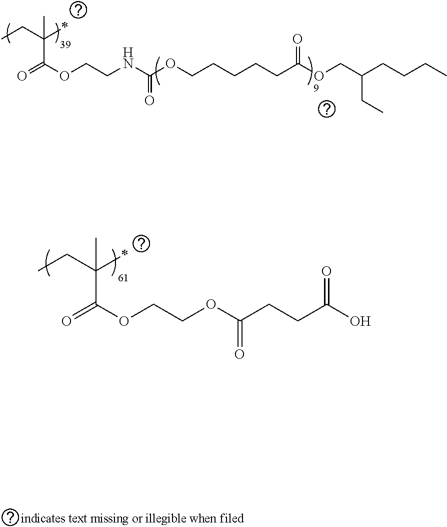

(Binder)

B-1: resin having the following structure (a numerical value added to a main chain represents a molar ratio; Mw=10,000, acid value-70 mgKOH/g)

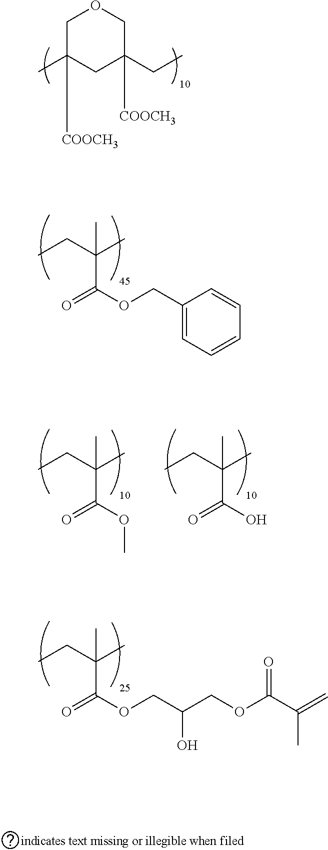

(Polymerizable Compound)

M-1: NK ESTER A-TMMT (manufactured by Shin-Nakamura Chemical Co., Ltd.)

(Photopolymerization Initiator)

I-1: compound having the following structure (Hansen solubility parameter=20.6 MPa^{0.5})

I-2: compound having the following structure (Hansen solubility parameter=22.1 MPa^{0.5})

I-3: compound having the following structure (Hansen solubility parameter 20.1 MPa^{0.5})

I-4: compound having the following structure (Hansen solubility parameter=21.3 MPa^{0.5})

I-5: compound having the following structure (Hansen solubility parameter=21.0 MPa^{0.5})

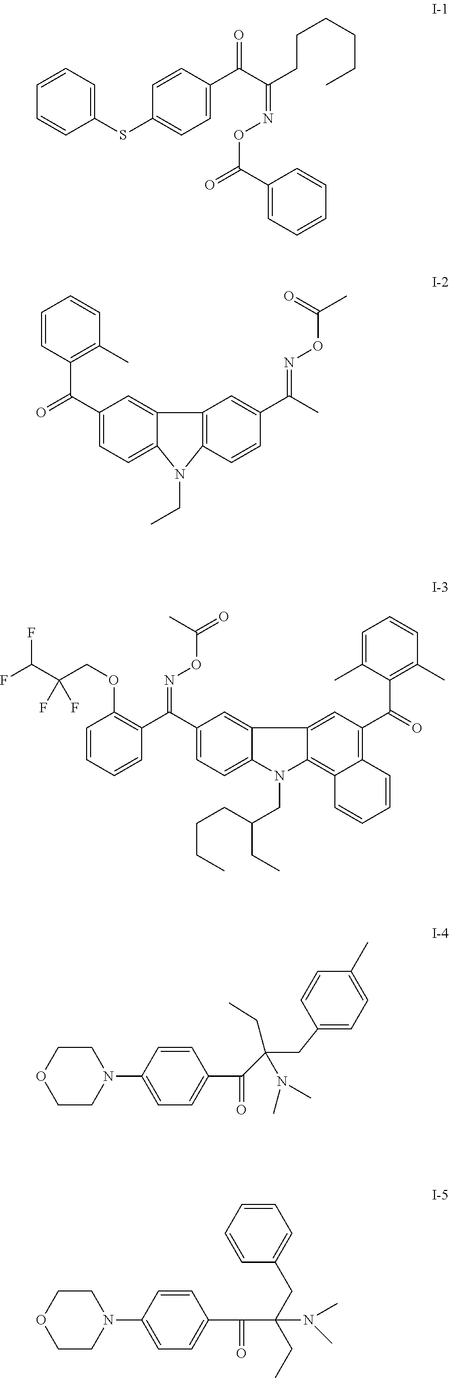 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCCCC(CC)Cn1c2ccc(/C(=N\OC(C)=O)c3ccccc3OCC(F)(F)C(F)F)cc2c2cc(C(=O)c3c(C)cccc3C)c3ccccc3c21 ; CCC(Cc1ccc(C)cc1)(C(=O)c1ccc(N2CCOCC2)cc1)N(C)C ; CCC(Cc1ccccc1)(C(=O)c1ccc(N2CCOCC2)cc1)N(C)C]

(Surfactant)

F-1: compound having the following structure (fluorine-based surfactant, weight-average molecular weight=14000; a numerical value “%” representing the proportion of a repeating unit is mol %)

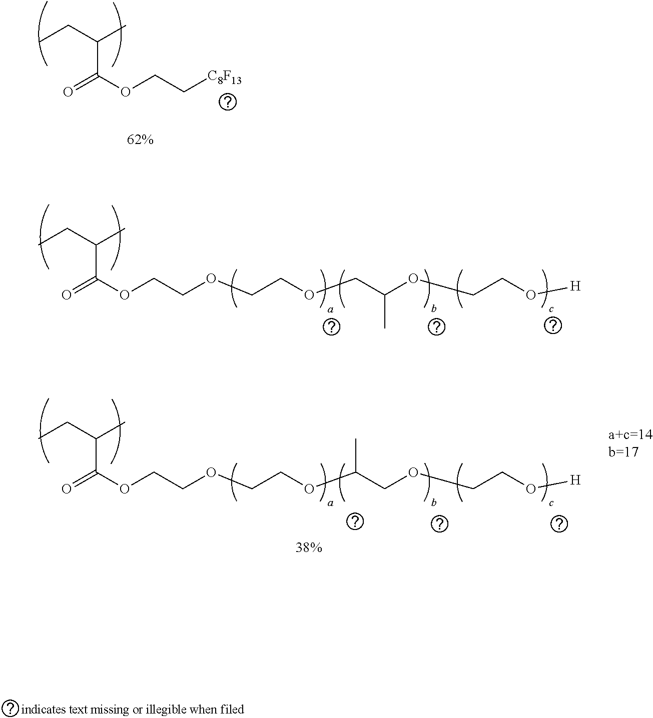

F-2: compound having the following structure (silicone-based surfactant, carbinol-modified silicone compound; weight-average molecular weight=3000, kinematic viscosity at 25° C.=45 mm²/s)

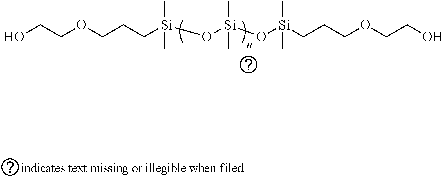

(Solvent)

[Solvent A1 (solvent in which surface tension at 25° C. is 28.0 mN/m or more, viscosity at 25° C. is 5.0 mPa-s or less, and boiling point is 160° C. or higher)]

A1-1: cyclohexyl acetate (surface tension at 25° C. 30.5 mN/m, viscosity at 25° C. 2.0 mPa·s, boiling point: 173° C., Hansen solubility parameter: 18.2 MPa^{0.5})

A1-2: 3-methoxy-1-butanol (surface tension at 25° C.=28.9 mN/m, viscosity at 25° C.=2.9 mPa·s, boiling point: 161° C., Hansen solubility parameter: 21.2 MPa^{0.5})

A1-3: 1,2-diacetoxypropane (surface tension at 25° C.=31.2 mN/m, viscosity at 25° C.=2.7 mPa·s, boiling point: 190° C., Hansen solubility parameter: 19.1 MPa^{0.5})

[Solvent Other than Solvent A1]

A2-1: propylene glycol monomethyl ether acetate (surface tension at 25° C.=26.7 mN/m, viscosity at 25° C.=1.1 mPa·s, boiling point: 146° C., Hansen solubility parameter: 19.3 MPa^{0.5})

A2-2: triacetin glycerin triacetate (surface tension at 25° C.=35.2 mN/m, viscosity at 25° C.=17.5 mPa·s, boiling point: 260° C., Hansen solubility parameter: 19.4 MPa^{0.5})

A2-3: 3-methoxybutyl acetate (surface tension at 25° C.=27.9 mN/m, viscosity at 25° C.=1.2 mPa·s, boiling point: 171° C., Hansen solubility parameter: 17.8 MPa^{0.5})

<Evaluation of Pattern Uniformity>

The photosensitive composition produced above was applied to a 8 inch (203.2 mm) silicon substrate with an undercoat layer using a spin coater such that a film thickness after pre-baking was 0.5 μm, and pre-baking was performed for 120 seconds using a hot plate at 100° C. to form a photosensitive composition layer. Using an i-ray stepper exposure device FPA-3000i5+ (manufactured by Canon Inc.), the photosensitive composition layer was irradiated with light with a wavelength of 365 nm through a 1.0 μm square island pattern mask to perform exposure thereon with an exposure amount of 400 mJ/cm². Next, the silicon substrate on which the photosensitive composition layer after the exposure was formed was placed on a horizontal rotary table of a spin-shower developing machine (DW-30 Type, manufactured by Chemitronics Co., Ltd.), subjected to a puddle development at 23° C. for 60 seconds using a developer (CD-2000, manufactured by Fujifilm Electronics Materials), and rinsed with water, thereby forming a 1.0 μm square pixel. A line width of the pixel was measured at 405 points (measuring line widths of 405 pixels) with a length-measuring scanning electron microscope (S-9260A, manufactured by Hitachi High-Tech Corporation), a line width (W1) of the pixel with the thickest line width and a line width (W2) of the pixel with the thinnest line width were each obtained, and a pattern uniformity was evaluated according to the following evaluation standard.

5: value of the line width (W1)—the line width (W2) was 50 nm or less.

4: value of the line width (W1)—the line width (W2) was more than 50 nm and less than 70 nm.

3: value of the line width (W1)—the line width (W2) was more than 70 nm and less than 100 nm.

2: value of the line width (W1)—the line width (W2) was more than 100 nm and less than 140 nm.

1: value of the line width (W1)—the line width (W2) was more than 140 nm.

<Temporal Stability>

The photosensitive composition prepared above was stored at 45° C. for 3 days. A viscosity of the photosensitive composition before and after the storage was measured, and a temporal stability of the photosensitive composition was evaluated using a value of the rate of change in viscosity calculated from the following expression. A viscosity of the photosensitive composition was measured with a viscometer (product name “RE-85 type viscometer, manufactured by Toki Sangyo Co., Ltd.). Measurement conditions of the viscosity were set to a rotation speed of 20 rpm and a temperature of 25° C.

Rate of change in viscosity=|1−(Viscosity of photosensitive composition after storage/Viscosity of photosensitive composition before storage)|×100

5: rate of change in viscosity was 10% or less.

4: rate of change in viscosity was more than 10% and 15% or less.

3: rate of change in viscosity was more than 15% and 20% or less.

2: rate of change in viscosity was more than 20% and 30% or less.

1: rate of change in viscosity was more than 30%.

The above-described evaluation results are shown in the table below. In addition, the content of the solvent A1 (solvent in which the surface tension at 25° C. was 28.0 mN/m or more, the viscosity at 25° C. was 5.0 mPa·s or less, and the boiling point was 160° C. or higher) in the total amount of the solvent of the photosensitive composition and the content of the coloring material (coloring material concentration) in the total solid content of the photosensitive composition are shown in the table below.

TABLE 2

| | Content of | | | |
|---|---|---|---|---|
| | solvent A1 in | Coloring | | |
| | total amount | material | Pattern | Temporal |
| | of solvent | concentration | uniformity | stability |
| Example 1 | 25% by mass | 40% by mass | 3 | 5 |
| Example 2 | 35% by mass | 40% by mass | 3 | 5 |
| Example 3 | 45% by mass | 40% by mass | 4 | 4 |
| Example 4 | 55% by mass | 40% by mass | 4 | 4 |
| Example 5 | 35% by mass | 40% by mass | 4 | 4 |
| Example 6 | 45% by mass | 40% by mass | 5 | 3 |
| Example 7 | 35% by mass | 40% by mass | 5 | 5 |
| Example 8 | 45% by mass | 40% by mass | 5 | 5 |
| Example 9 | 45% by mass | 40% by mass | 5 | 5 |
| Example 10 | 45% by mass | 40% by mass | 5 | 5 |
| Example 11 | 45% by mass | 40% by mass | 5 | 5 |
| Example 12 | 45% by mass | 40% by mass | 4 | 5 |
| Example 13 | 45% by mass | 40% by mass | 4 | 5 |
| Example 14 | 45% by mass | 40% by mass | 5 | 5 |
| Example 15 | 45% by mass | 40% by mass | 4 | 5 |
| Example 16 | 45% by mass | 40% by mass | 4 | 5 |
| Example 17 | 45% by mass | 40% by mass | 4 | 5 |
| Example 18 | 45% by mass | 40% by mass | 3 | 5 |
| Comparative | 0% by mass | 40% by mass | 1 | 3 |
| Example 1 | | | | |
| Comparative | 0% by mass | 40% by mass | 2 | 4 |
| Example 2 | | | | |

As shown in the above table, the photosensitive compositions of Examples have a better evaluation of the pattern uniformity than that of Comparative Examples, and it was possible to form a pixel with less variation in pattern size (line width) than that of Comparative Examples.

What is claimed is:

1. A photosensitive composition comprising:
a coloring material;
a resin;
a polymerizable compound;
a photopolymerization initiator; and
a solvent A,
wherein the solvent A includes a solvent A1 in which a surface tension at 25° C. is 28.0 mN/m or more, a viscosity at 25° C. is 5.0 mPa s or less, and a boiling point is 160° C. or higher, and
a content of the solvent A1 in a total amount of the solvent A is 15% by mass or more.

2. The photosensitive composition according to claim 1, further comprising:
a surfactant.

3. The photosensitive composition according to claim 1,
wherein the boiling point of the solvent A1 is 160° C. to 280° C.

4. The photosensitive composition according to claim 1,
wherein a Hansen solubility parameter of the solvent A1 is 18.0 to 22.0 MPa^{0.5}.

5. The photosensitive composition according to claim 1,
wherein the solvent A1 is at least one selected from cyclohexyl acetate, 3-methoxy-1-butanol, or 1,2-diacetoxypropane.

6. The photosensitive composition according to claim 1,
wherein an absolute value of a difference between a Hansen solubility parameter of the photopolymerization initiator and a Hansen solubility parameter of the solvent A1 is 4.5 MPa^{0.5} or less.

7. The photosensitive composition according to claim 1,
wherein the coloring material includes a pigment.

8. The photosensitive composition according to claim 1,
wherein the photosensitive composition contains the coloring material in an amount of 38% by mass or more in a total solid content of the photosensitive composition.

9. A method for forming a pixel, comprising:
applying the photosensitive composition according to claim 1 to a support to form a photosensitive composition layer;
exposing the photosensitive composition layer in a patterned manner; and
removing a non-exposed portion of the photosensitive composition layer after exposure by development.

10. The method for forming a pixel according to claim 9,
wherein the photosensitive composition is applied to the support by a spin coating method to form the photosensitive composition layer.

11. A method for manufacturing an optical filter, comprising:
the method for forming a pixel according to claim 9.

12. A method for manufacturing a solid-state imaging element, comprising:
the method for forming a pixel according to claim 9.

13. A method for manufacturing an image display device, comprising:
the method for forming a pixel according to claim 9.
